(19) United States
(12) Patent Application Publication
(10) Pub. No.: US 2023/0401487 A1
(43) Pub. Date: Dec. 14, 2023

(54) METHOD, SYSTEM AND COMPUTER PROGRAM PRODUCT FOR PROVIDING INSIGHTS ON USER DESIRABILITY

(71) Applicant: SPG DRY COOLING BELGIUM SRL, Bruxelles (BE)

(72) Inventors: Andreas COUMNAS, Bruxelles (BE); Christophe DELEPLANQUE, Bruxelles (BE); Sanjeev NARAYANAN, Bruxelles (BE)

(21) Appl. No.: 18/250,436

(22) PCT Filed: Oct. 28, 2021
(86) PCT No.: PCT/EP2021/080001

§ 371 Date: Apr. 25, 2023

(30) Foreign Application Priority Data
Oct. 30, 2020 (BE) BE2020/5779

(51) Int. Cl. G06N 20/00; G06F 30/13

(52) U.S. Cl. CPC G06N 20/00; G06F 30/13

(57) ABSTRACT

The present invention pertains to a method, system and computer program product for providing insights on user desirability on database-stored computer-aided design (CAD) knowledge models, as well as use thereof for managing CAD-knowledge models of cooling installations.

### FIELD OF THE INVENTION

The present invention pertains to a method, system and computer program product for providing insights on user desirability on database-stored computer-aided design (CAD) knowledge models.

### BACKGROUND

CAD has been used to aid in the design and especially the drafting of a part or product. It is both a visual (or drawing) and symbol-based method of communication whose conventions are particular to a specific technical field. Drafting can be done in two and three dimensions.

CAD is mainly used for detailed engineering of 3D models and/or 2D drawings of physical components, but it is also used throughout the engineering process from conceptual design and layout of products, through strength and dynamic analysis of assemblies to definition of manufacturing methods of components.

Furthermore, CAD enables designers to store various design know-how and verification standards in a CAD model and share the model with engineers by making it a template. However, workload is significantly increased when knowledge is changed (e.g., based on new discoveries). This makes it necessary to change not only the template but also all CAD models based on the template.

Systems that make knowledge, which originated from a CAD model, available to other CAD systems and applications are known in the art, e.g. U.S. Pat. No. 2,010,042 658, US 2019114376 and WO 2020 055 659. However, known systems such as described in US '658 and US '659 lack the ability to predict desired outcomes of a project and solely act as a source of information.

A system capable of providing the user with desired outcomes can be found in US 2019026403. US '403 makes use of machine learning in order to assess outcome desirability, however, desirability is assessed for each case in very limited terms of ‘yes’ or ‘no’ indicators.

There remains a need in the art for a method, system and computer program product for providing insights on user desirability and especially for providing well-informed and hence a limited amount of suggestions.

The invention aims to resolve at least some of the technical problems associated with methods, systems and computer program products known in the art.

### SUMMARY OF THE INVENTION

In a first aspect the present invention relates to a computer-implemented method for providing insights on user desirability according to claim 1.

In a second aspect the present invention relates to a computer system for providing insights on user desirability according to claim 13.

In a third aspect the present invention relates to a computer program product for providing insights on user desirability according to claim 14.

In a fourth aspect the present invention relates to use of the invention according to a first, second or third aspect according to claim 15.

The invention is advantageous as the machine learning module can be trained via the set of records, thereby learning user desirability on specific input and output values depending on at least one CAD-identifier. This significantly simplifies the computer-aided design process, as user modelling of different parameters of projects can be replaced by well-informed and hence a limited amount of suggestions.

Furthermore, the present invention allows for continuous learning, as acceptance or decline of a suggestion can be used to further train the module.

Preferred embodiments of the invention are discussed in claims 2 to 12, as well as throughout the description, examples and figures.

### DESCRIPTION OF FIGURES

FIG. 1 shows a schematic structure of a database according to the invention.

FIG. 2 shows a schematic overview of the training the computer-implemented machine learning module according to the invention.

### DETAILED DESCRIPTION OF THE INVENTION

The present invention concerns a method, system, computer program product for providing insights on user desirability, and use of the method, system and computer program product for providing insights on user desirability of cooling installations. In what follows, the invention will be described in detail, preferred embodiments are discussed and the invention will be illustrated by means of non-limitative examples.

Unless otherwise defined, all terms used in disclosing the invention, including technical and scientific terms, have the meaning as commonly understood by one of ordinary skill in the art to which this invention belongs. By means of further guidance, term definitions are included to better appreciate the teaching of the present invention.

As used herein, the following terms have the following meanings:

“A”, “an”, and “the” as used herein refers to both singular and plural referents unless the context clearly dictates otherwise. By way of example, “a compartment” refers to one or more than one compartment.

“Comprise”, “comprising”, and “comprises” and “comprised of” as used herein are synonymous with “include”, “including”, “includes” or “contain”, “containing”, “contains” and are inclusive or open-ended terms that specifies the presence of what follows e.g. component and do not exclude or preclude the presence of additional, non-recited features, element, steps, etc., known in the art or disclosed therein.

Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the invention described herein are capable of operation in other sequences than described or illustrated herein.

Whereas the terms “one or more” or “at least one”, such as one or more or at least one member(s) of a group of members, is clear per se, by means of further exemplification, the term encompasses inter alia a reference to any one of said members, or to any two or more of said members, such as, e.g., any ≥3, ≥4, ≥5, 6 or 7 etc. of said members, and up to all said members.

Unless otherwise defined, all terms used in disclosing the invention, including technical and scientific terms, have the meaning as commonly understood by one of ordinary skill in the art to which this invention belongs. By means of further guidance, definitions for the terms used in the description are included to better appreciate the teaching of the present invention. The terms or definitions used herein are provided solely to aid in the understanding of the invention.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to a person skilled in the art from this disclosure, in one or more embodiments. Furthermore, while some embodiments described herein include some but not other features included in other embodiments, combinations of features of different embodiments are meant to be within the scope of the invention, and from different embodiments, as would be understood by those in the art. For example, in the following claims, any of the claimed embodiments can be used in any combination.

In a first aspect, the invention pertains to a computer-implemented method for providing insights on user desirability. The method preferably comprising the step of providing a database for managing a plurality of computer-aided design (CAD) knowledge models. The database preferably comprising for each knowledge model a plurality of input and output data fields and a plurality of calculation modules. Preferably, wherein each data field comprises a data slot for receiving a value and a CAD-identifier corresponding to a parameter of a parametric CAD-model. Preferably, wherein each calculation module couples a value of a corresponding input and output data slot via a formula. The method preferably further comprising the step of obtaining a set of training records for each input CAD-identifier, wherein each of said training records is obtained by: receiving a starting training input value in one of the input data slots of the database, wherein for said starting training input value a corresponding starting training output value is obtained by means of one or more corresponding calculation modules; obtaining a modification to the starting training input or output value, wherein for said modified value a proposed corresponding training input or output value is obtained for said knowledge model by means of one or more corresponding calculation modules; obtaining an acceptation indicator for the proposed corresponding training input or output value, wherein said input and output values are thereby registered as a desired training input or output value; preferably wherein each of said training records at least comprises the starting training input value and the corresponding desired training input value. The method preferably further comprising the step of training a computer-implemented machine learning module for each input CAD-identifier based on the corresponding set of training records. The method preferably further comprising the step of providing a starting input value in an input data slot of a CAD-knowledge model, wherein for said starting input value a corresponding output value is obtained by means of one or more corresponding calculation modules. The computer-implemented method preferably further comprising the step of obtaining a proposed desired input value by means of the trained computer-implemented machine learning module.

In a second aspect, the invention pertains to a computer system for providing insights on user desirability. The computer system preferably comprising a database for managing a plurality of CAD knowledge models. Preferably, wherein the database comprises for each knowledge model a plurality of input and output data fields and a plurality of calculation modules. Preferably, wherein each data field comprises a data slot for receiving a value and a CAD-identifier corresponding to a parameter of a parametric CAD-model. Preferably, wherein each calculation module couples a value of a corresponding input and output data slot via a formula. Preferably, wherein the computer system is configured for obtaining a set of training records for each input CAD-identifier, wherein each of said training records is obtained by: receiving a starting training input value in one of the input data slots of the database, wherein for said starting training input value a corresponding starting training output value is obtained by means of one or more corresponding calculation modules; obtaining a modification to the starting training input or output value, wherein for said modified value a proposed corresponding training input or output value is obtained for said knowledge model by means of one or more corresponding calculation modules; obtaining an acceptation indicator for the proposed corresponding training input or output value, wherein said input and output values are thereby registered as a desired training input or output value; preferably wherein each of said training records at least comprises the starting training input value and the corresponding desired training input value. Preferably, wherein the system is further configured for training a computer-implemented machine learning module for each input CAD-identifier based on the corresponding set of training records. Preferably, wherein the system is configured for providing a starting input value in an input data slot of a CAD-knowledge model, wherein for said starting input value a corresponding output value is obtained by means of one or more corresponding calculation modules. Preferably, wherein the system is configured for obtaining a proposed desired input value by means of the trained computer-implemented machine learning module.

In a third aspect, the invention pertains to a computer program product for providing insights on user desirability. The computer program product preferably comprising instructions for providing a database for managing a plurality of CAD knowledge models. Preferably, wherein the database comprises for each knowledge model a plurality of input and output data fields and a plurality of calculation modules. Preferably, wherein each data field comprises a data slot for receiving a value and a CAD-identifier corresponding to a parameter of a parametric CAD-model. Preferably, wherein each calculation module couples a value of a corresponding input and output data slot via a formula. The computer program product preferably further comprising instructions for obtaining a set of training records for each input CAD-identifier, wherein each of said training records is obtained by: receiving a starting training input value in one of the input data slots of the database, wherein for said starting training input value a corresponding starting training output value is obtained by means of one or more corresponding calculation modules; obtaining a modification to the starting training input or output value, wherein for said modified value a proposed corresponding training input or output value is obtained for said knowledge model by means of one or more corresponding calculation modules; obtaining an acceptation indicator for the proposed corresponding training input or output value, wherein said input and output values are thereby registered as a desired training input or output value; preferably wherein each of said training records at least comprises the starting training input value and the corresponding desired training input value. The computer program product preferably further comprising instructions for training a computer-implemented machine learning module for each input CAD-identifier based on the corresponding set of training records. The computer program product preferably further comprising instructions for providing a starting input value in an input data slot of a CAD-knowledge model, wherein for said starting input value a corresponding output value is obtained by means of one or more corresponding calculation modules. The computer program product preferably further comprising instructions for obtaining a proposed desired input value by means of the trained computer-implemented machine learning module.

In a fourth aspect, the invention pertains to a use of the invention according to any of the first, second or third aspect of the inventions, for providing insights on user desirability of cooling installations.

The present disclosure provides a computer-implemented method, a computer program product, a computer system, and a use of any of the method, the computer program product, or the computer system for providing insights on user desirability. A person having ordinary skill in the art will appreciate that the computer-implemented method is implemented in the computer program product and executed using the computer system. A person having ordinary skill in the art will also appreciate that any of the method, computer program product, or computer system are is suited for providing insights on user desirability of cooling installations. In what follows, the four aspects of the present invention are therefore treated together.

“Computer-aided design model” or “CAD-model,” as used herein, comprises computer-processable data, preferably digital data, about one or more solids, said data representing, or allowing to derive, properties of the solids, such as geometric properties, material properties and/or semantic properties. Said data may also represent, or may allow to derive, relative geometric properties between solids. CAD-model, as used herein, is preferably a parametric CAD-model, which, as used herein, comprises a family of probability distributions that has a finite number of parameters.

A CAD model may be viewed and/or edited via a corresponding CPP, so-called CAD software. A non-limiting list of CAD software comprises 123D, ACIS, Advance Concrete, Advance Design, Advance Steel, AllyCAD, ArchiCAD, AutoCAD, ‘Autodesk Inventor’, ‘AutoCAD Plant 3D’, ‘Autodesk Robot’, BricsCAD, BRL-CAD, C3D, Caddie, Cadwork, CATIA, Chief Architect, Cobalt, Creo, DataCAD, DesignSpark Mechanical, Digital Project, Drawing Express, FINE MEP, form»Z, FreeCAD, HiCAD, IDEA Architectural, IRONCAD, ItelliCAD, KeyCreator, LibreCAD, MEDUSA, MicroStation, Modelur, NanoCAD, NX, OpenCASCADE, OpenSCAD, Parasolid, PTC Creo, PowerCADD, progeCAD, PunchCAD, QCad, Revit Architecture, Revit MEP, Revit Structure, Rhinoceros 3D, RoutCad, SALOME, ShapeManager, SketchUp, Solid Edge, SolidWorks, SolveSpace, SpaceClaim, SpaceClaim Engineer, Tekla Structures, TopSolid, TransMagic, TurboCAD, VariCAD, VectorWorks, and VisualARQ. A non-limiting list of BIM software comprises Allplan, ArchiCAD, ARCHLine.XP, Autodesk Revit, BricsCAD, CodeBook, DDS-CAD, Digital Project, GRAITEC Advance, IDEA Architectural, MicroStation, Navisworks, OpenStudio, RFEM, Tekla BIMsight, Tekla Structures, Trimble SketchUp, VectorWorks Architect, Vico Office, and VisualARQ.

A CAD model, as used herein, is preferably a “building information model” or “BIM-model”. One of ordinary skill in the art will appreciate that while the present invention preferentially involves a BIM, it may also be used for CAD models in different fields, such as, for example, mechanical engineering. BIM involves representing a design as combinations of “objects,” which are vague and undefined, generic or product-specific, solid shapes or void-space oriented (like the shape of a room), that carry their geometry, relations and attributes. Furthermore, BIM design tools allow extraction of different views from a building model for drawing production and other uses. These different views are automatically consistent, being based on a single definition of each object instance. BIM software also defines objects parametrically; that is, the objects are defined as parameters and relations to other objects, so that if a related object is amended, dependent ones will automatically also change. Moreover, each model element can carry attributes for selecting and ordering them automatically, providing cost estimates as well as material tracking and ordering.

Building information modelling (BIM) is a process involving the generation and management of digital representations of physical and functional characteristics of places. BIMs are files (often but not always in proprietary formats and containing proprietary data) which can be exchanged or networked to support decision-making about a place. Current BIM software is used by individuals, businesses and government agencies who plan, design, construct, operate and maintain diverse physical infrastructures, such as water, wastewater, electricity, gas, refuse and communication utilities, roads, bridges and ports, houses, apartments, schools and shops, offices, factories, warehoused and prisons. Traditional building design was largely reliant upon two-dimensional drawings (plans, elevations, sections, etc.). Building information modelling extends this beyond 3D, augmenting the three primary spatial dimensions (width, height and depth) with time as the fourth dimension and cost as the fifth dimension. BIM therefore covers more than just geometry. It also covers spatial relationships, light analysis, geographic information, quantities and properties of components (for example, manufacturers' details).

A simple embodiment of the present invention provides a database for management of a plurality of CAD-knowledge models. A CAD-knowledge model describing, non-limitative a system, operational characteristics thereof, as well as their relation to an environment. By storing such CAD-knowledge model on a database, a central truth of a project can be provided to different teams with different specialties, working on different aspect of a project. A simple embodiment of a CAD-knowledge model comprises a plurality of input and output data fields. Each of said input and output fields comprising a data slot and a CAD-identifier. A data slot is suitable to receive a value, i.e. an input or output value. Input values are preferably provided to data slots by a user. Input values furthermore may or may not be provided (automatically) by a program, via for example a feedback loop. Output values are preferably provided to data slots via one or more calculation modules transforming one or more corresponding input values. Output values furthermore may or may not be provided (automatically) by a program, via for example a feedback loop. A simple embodiment of a CAD-knowledge model furthermore comprises a CAD-identifier associated with a data slot. These identifiers correspond to a parameter of a parametric CAD-model. As such, the values and corresponding identifiers can be imported in a CAD-program or application to therefrom generate a model.

According to a preferred embodiment, a CAD-knowledge model further comprises, for each of the input and output data fields, one or more of a component indicator, a package indicator, a project indicator and a unit associated to the value. In order to maintain overview of a project, such as construction of an industrial plant, each of the input and output data fields are preferably provided with a hierarchical project indicator. Preferably, these hierarchical project indicators refer to a project at a component-, package- and project-level. As such, allowing easy overview of the project. Furthermore, in order to improve readability of the data fields of a knowledge models a unit associated to the value. This unit may serve as improving readability but may also be used to provide a current unit to a CAD-application when importing the values from the database. Alternatively, when importing the values to a CAD-application the units are comprised by the corresponding CAD-identifier.

According to a preferred embodiment, a CAD-knowledge model further comprises, for each of the input and output data fields, a view-indicator. Preferably, the database further comprises an interface module comprising a view selector module. Preferably, wherein depending on each of the view-indicators of the data fields, the view selector module determines which data fields are shown by the interface module. Such implementation improves user-friendliness of the database. For example, depending on the user of the database, different data fields might be shown via the user interface, i.e. a manager working on a project can be shown different data fields compared to a engineer working on a component-level. The user may for example be recognised by means of login-module. Furthermore, this login-module may for example request an identification code, password, etc. Furthermore, depending on each of the view-indicators of the data fields, the view selector module may or may not determine the sequence by which the elements in the data fields are shown by the interface module, or which are or are not shown by the interface.

According to a preferred embodiment, the plurality of calculation modules are provided to the database for a CAD-knowledge model as one or more of a flat file, a structured file, a relational table or an XML data file. Such structured data files are easy to read by an operator and application. After providing these calculation modules to the database, the calculation modules can be stored in an appropriated data format. Preferably, the calculation modules are stored as a “JavaScript Object Notation” (JSON) file on the database. JSON is an open standard file format, and data interchange format, that uses human-readable text to store data objects consisting of attribute-value pairs and array data types (or any serializable value).

According to a preferred embodiment, the plurality of input values are provided in the input data slots of a CAD-knowledge model as one or more of a flat file, a structured file, a relational table or an XML data file.

According to a preferred embodiment, a CAD-knowledge model can be exported from the database as one or more of a flat file, a structured file, a relational table or an XML data file. For example, the model is exported as a data sheet or DNO/report.

A simple embodiment of the present invention furthermore comprises providing at least some of the values comprised by the plurality input and output data slots of said CAD-knowledge model to a CAD-module suitable for generating a parametric three-dimensional CAD-model. “CAD-module,” as used herein, comprises one or more CAD-programs or applications. Any of the examples listed hereabove can thus be comprised by a CAD-module. Preferably, the CAD-module comprises one or more of a CAD-application for mechanical design, a CAD-application for design of structural loads and a CAD-application for process design of plant facilities. Accordingly, the invention may or may not provide one or more of the following applications: ‘Autodesk Inventor’, ‘Autodesk Robot’, ‘AutoCAD’ and ‘AutoCAD Plant 3D’. Other applications or combinations of applications are naturally also applicable to the inventions. Preferably, the one or more CAD-applications of the CAD-module are coupled via a building information modelling (BIM) application. By storing values of such knowledge model in the database, a central truth of a project can be provided to different teams with different specialties, working on different aspect of a project.

According to an embodiment, the input and output data fields of a knowledge model are stored in the database as one or more of a flat file, a structured file, a relational table or an XML data file. Preferably, the input and output data fields of a knowledge model are stored in the database as a flat file. More preferably, wherein each of the input and output data fields of a knowledge model are stored in the database as a string in a flat file. Even more preferably, wherein elements of a data field in a string of a flat file are separated by means of a separation symbol. Flat files, structured files, etc. are easy to read by both a user and a program. Flat files are particularly advantageous as they follow a uniform format, and there are no structures for indexing or recognizing relationships between records. By providing the different data fields as strings in a flat file, the information is easy to read by a user. Suitable separation symbols include, but are not limited to, logical operators such as ‘=’, ‘≠’, ‘<’, ‘≤’, ‘>’, ‘>’, or combinations thereof, Boolean operators such as ‘&’, ‘&&’, ‘I’, ‘II’, or combinations thereof, etc. Preferably, ‘=’ is used as separator. The information stored in the database, e.g. as a flat file, is used for communication between database and CAD-module. Preferably, said communication occurs trough an API.

According to an embodiment, the invention comprises obtaining a three-dimensional parametric CAD-model from the provided values of a knowledge model by means of said CAD-module. In order to match the exported values with the to be create CAD-model, each CAD-identifier from a data field in the database for said knowledge model corresponds to a parameter of the parametric CAD-model. The CAD-module may or may not be provided on a separate computer system as the database. The CAD-module may or may not be provided on the same computer system as the database. Preferably, the database is provided in a database server, more preferably a cloud server. Preferably, the CAD-module is provided in a server in connection, via for example the internet, to said database server. The CAD-module may or may not be provided on different servers, each in connection with said database server. Such configuration allows providing a central truth of a project to different teams with different specialties, working on different aspect of said project.

A simple embodiment of the present invention furthermore comprises obtaining a set of training records for each input CAD-identifier, and training a computer-implemented machine learning module for each input CAD-identifier based on the corresponding set of training records. Such module is advantageous as it can be trained via the set of records, thereby learning user desirability on specific input and output values depending on at least one CAD-identifier. This significantly simplifies the computer-aided design process, as user modelling of different parameters of projects can be replaced by well-informed and hence a limited amount of suggestions. Preferably, each of said training records at least comprising the starting training input value and the corresponding desired training input value.

Preferably, each of said training records is obtained by: receiving a starting training input value in one of the input data slots of the database, wherein for said starting training input value a corresponding starting training output value is obtained by means of one or more corresponding calculation modules; obtaining a modification to the starting training input or output value, wherein for said modified value a proposed corresponding training input or output value is obtained for said knowledge model by means of one or more corresponding calculation modules, preferably by means of one or more corresponding calculation modules or user experiences; and obtaining an acceptation indicator for the proposed corresponding training input or output value, wherein said input and output values are thereby registered as a desired training input or output value. Preferably, wherein modification to the starting training input or output value occurs due to a user action. All of the above preferences and features duly improve collection of user preference data.

“Artificial intelligence” or short “AI,” as used herein, refers to a field pertaining to machine mimicking of cognitive functions. The central problems of AI research include reasoning, knowledge, planning, learning, natural language processing, perception, and the ability to manipulate objects. Approaches include statistical methods, computational intelligence, and traditional symbolic AI. The AI field draws upon computer science, mathematics, psychology, linguistics, philosophy, neuroscience, artificial psychology, and many others. Capabilities classified as AI include successfully understanding human speech, competing at a high level in strategic game systems, autonomous cars, intelligent routing in content delivery networks, interpreting complex data, and the like. The AI field encompasses the field of machine learning. A non-limiting list of techniques used in machine learning comprises decision tree learning, association rule learning, artificial neural networks, deep learning, inductive logic programming, support vector machines, clustering, Bayesian networks, reinforcement learning, representation learning, similarity and metric learning, sparse dictionary learning, genetic algorithms, rule-based machine learning, and learning classifier systems. A non-limiting list of software programs and/or libraries used for machine learning includes Apache SINGA, Caffe, Deeplearning4j, Dlib, Keras, Microsoft Cognitive Toolkit, Microsoft Computational Network Toolkit, MXNet, Neural Designer, OpenNN, Pytorch, Scikit-learn for the Python programming language, TensorFlow, Theano, Torch, Wolfram Mathematica.

After training of the computer-implemented machine learning module, the method furthermore comprises providing a starting input value in an input data slot of a CAD-knowledge model, wherein for said starting input value a corresponding output value is obtained by means of one or more corresponding calculation modules. This new input value may for example represent a new value for a project. By means of the trained computer-implemented machine learning module a proposed desired input value can be obtained. Thus, further improving efficiency of the new project.

According to a preferred embodiment, obtaining an acceptation indicator for the proposed corresponding starting input or output value occurs by means of a binary indicator, which is positive in case of accepting and negative in case of declining. One of ordinary skill in the art will appreciate that “positive” and “negative” as used herein refer to two possibilities for binary input, and may in practice be embodied differently, such as, for example, by “1” and “0”, and the like. The computer-implemented machine learning module may hereby be trained to categorize user desirability of a detail, whereby two categories are available, e.g. “positive” and “negative,” “desired” and “undesired,” “1” and “0,” and the like. However, preferably, a predicted user desirability may comprise one of many (more than two) possible numerical values. A predicted user desirability may, for example, be a predicted percentage likelihood of (“positive”) user desirability. Accordingly, obtaining an acceptation indicator for the proposed corresponding starting input or output value may or may not preferably occurs by means of a score.

According to a preferred embodiment, the computer-implemented machine learning module comprises an algorithm based on machine learning and/or statistical learning. Thus, the module may or may nor be trained for pattern recognition in relation to user detail insertion. Preferably, the computer-implemented machine learning module comprises an algorithm based on an artificial neural network, a support vector machine, or decision tree. The applicant has found that the specific choice of either an artificial neural network, a support vector machine, or a decision tree has only minor effect on the accuracy. The choice of input for the trainable module was found to be substantially more influential on the outcome. Accordingly, the set of training records for each input CAD-identifier comprises training records from two or more knowledge models, as a consequence achieving better results.

According to an embodiment, the computer-implemented machine learning module comprises an algorithm based on machine learning and/or statistical learning. Thus, the module may or may nor be trained for pattern recognition in relation to user detail insertion. From said pattern recognition, the computer-implemented machine learning module of the present embodiment can determine insight calculation modules, wherein each module couples values of input and output data slots via insight formulas, said formulas being determined from said pattern recognition.

According to an embodiment, a user interaction module is provided in operative communicative connection to the database and the computer-implemented machine learning module. The user interaction module being configured for one or more of remote control, STB button, voice-based commands, gesture-based commands, etc. The voice-based commands may be recognized and processed to identify one or more instructions to display the digital representation of the at least one asset. Processing of the voice-based command may be performed, for example, using natural language processing. Voice-based command enables hands-free handling of the digital representation. Therefore, such display of the digital representation may also be enabled when the user's hands are occupied in other tasks.

According to an embodiment, the CAD-module and the computer-implemented machine learning module in conjunction will be able to auto-rectify solutions and notify a concerned person for that specific change in a respective package/element.

### EXAMPLES AND DESCRIPTION OF FIGURES

The invention is further described by the following non-limiting examples which further illustrate the invention, and are not intended to, nor should they be interpreted to, limit the scope of the invention.

### Example 1: Database

The present example pertains to a preferred method for storing information in the database according to the present invention.

As discussed throughout the description, in order for a CAD-knowledge model to be stored in a user-friendly matter, the different data fields of a knowledge model have to be readable for both an operator and an application. Ideally, a flat file is used, wherein the different data fields are stored as strings and wherein the different element in said string are separated by means of a separator symbol, e.g. ‘=’.

An exert of such preferred flat file is shown below.

Staircase_NorthWest_X_Position=Staircase_NorthWest_X_Position=Straircase 1 x position=1960.00000000=mm=218-STAIRCASE;

Staircase_NorthWest_Y_Position=Staircase_NorthWest_Y_Position=Straircase 1 y position=104600=mm=218-STAIRCASE;

Staircase_SouthEast_X_Position=Staircase_SouthEast_X_Position=Straircase 2 x position=122995=mm=218-STAIRCASE;

Primary_Bundle_Top_Head_Mounting_Width=Primary_Bundle_Top_Head_Mountin g_Width=Primary Bundle Top Head Mounting Width=526.000=mm=215-A-FRAME;

MSD_Diameter_Reduction_LHS_1=MSD_Diameter_Reduction_LHS_1=MSD Diameter Reduction LHS 1=5400=mm=411-MAIN STEAM DUCT;

MSD_Diameter_Reduction_LHS_2=MSD_Diameter_Reduction_LHS_2=MSD Diameter Reduction LHS 2=3800=mm=411-MAIN STEAM DUCT;

MSD_Diameter_Reduction_LHS_3=MSD_Diameter_Reduction_LHS_3=MSD Diameter Reduction LHS 3=2700=mm=411-MAIN STEAM DUCT;

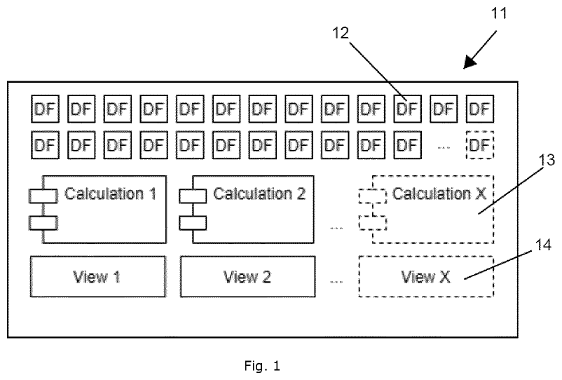

FIG. 1 shows a schematic structure of a database (11) according to the invention, comprising a plurality data fields (12), calculation modules (13), and views (14). In accordance with the above exert, each data field comprises an internal code, a CAD-identifier, a description, a value, a unit associated with the value and a component name, respectively, each separated by means of an ‘=’ as separator symbol. Strings in the flat file are separated by means of an ‘;’. The view-indicator can be based of any of the above elements. The view selector module determines which of the views are shown by the interface-module. The views can be predetermined.

### Example 2: Trained ML-module

The present example pertains to training of the computer-implemented machine learning (ML) module according to the invention.

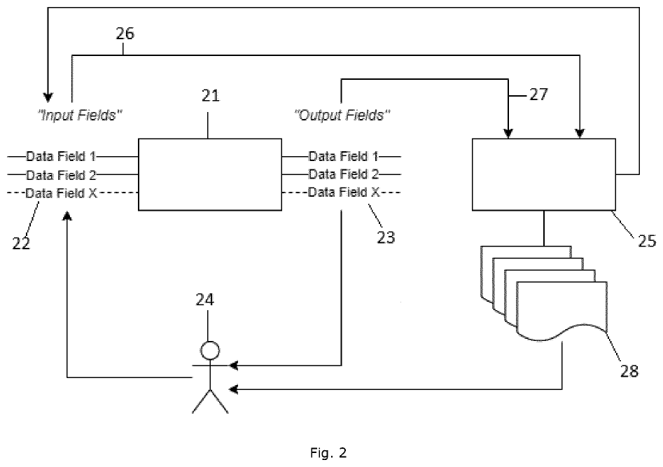

FIG. 2 shows a schematic overview of training the computer-implemented ML-module (25) of the invention. Furthermore, a database (21) is shown, wherein both the input data fields (22) and the output data fields (23) are illustrated to the left and right of the database, respectively. In order for a user (24) to obtain the desired balance between the input and output data fields, he/she needs to interpret the generated output data fields to thereafter manipulate the corresponding input data fields. To improve this process, the computer-implemented ML-module is trained for each input CAD-identifier by means of a set training records obtained from repetitive user-interaction with the database, preferably over different projects. After training, in- (26) and output (27) data fields for the ML-module are analysed by the trained ML-module to determine insights (28). The in- (26) and output (27) data fields for the ML-module are extracted from the in- (22) and output (23) data fields of the database. The insights from the trained ML-module can be corresponded to the user, who may in turn manipulate the corresponding input data fields. Alternatively, the ML-module can be configured to automatically manipulate the corresponding input data fields. Accordingly, automatically optimizing a knowledge model.

The present invention is in no way limited to the embodiments described in the examples and/or shown in the figures. On the contrary, methods according to the present invention may be realized in many different ways without departing from the scope of the invention.

1. Computer-implemented method for providing insights on user desirability, comprising the steps of:
providing a database for managing a plurality of computer-aided design (CAD) knowledge models, wherein the database comprises for each knowledge model a plurality of input and output data fields and a plurality of calculation modules, wherein each data field comprises a data slot for receiving a value and a CAD-identifier corresponding to a parameter of a parametric CAD-model, wherein each calculation module couples a value of a corresponding input and output data slot via a formula;
obtaining a set of training records for each input CAD-identifier, wherein each of said training records is obtained by:
receiving a starting training input value in one of the input data slots of the database, wherein for said starting training input value a corresponding starting training output value is obtained by means of one or more corresponding calculation modules;
obtaining a modification to the starting training input or output value, wherein for said modified value a proposed corresponding training input or output value is obtained for said knowledge model by means of one or more corresponding calculation modules, wherein the modification to the starting training input or output value occurs due to a user action; o obtaining an acceptation indicator for the proposed corresponding training input or output value,
wherein said input and output values are thereby registered as a desired training input or output value; wherein each of said training records at least comprises the starting training input value and the corresponding desired training input value;
training a computer-implemented machine learning module for each input CAD-identifier based on the corresponding set of training records;
providing a starting input value in an input data slot of a CAD-knowledge model, wherein for said starting input value a corresponding output value is obtained by means of one or more corresponding calculation modules;
obtaining a proposed desired input value for said starting input value by means of the trained computer-implemented machine learning module.

2. The method according to claim 1, wherein the computer-implemented machine learning module comprises an algorithm based on machine learning and/or statistical learning.

3. The method according to claim 1, wherein the computer-implemented machine learning module comprises an algorithm based on an artificial neural network, a support vector machine, or decision tree.

4. The method according to claim 1, wherein said set of training records for each input CAD-identifier comprises training records from two or more knowledge models.

5. The method according to claim 1, wherein obtaining an acceptation indicator for the proposed corresponding starting input or output value occurs by means of a binary indicator, which is positive in case of accepting and negative in case of declining.

6. The method according to claim 1, wherein obtaining an acceptation indicator for the proposed corresponding starting input or output value occurs by means of a score.

7. The method according to claim 1, wherein the database further comprises an interface module comprising a view selector module, wherein each of the input and output data fields further comprise a view-indicator, wherein depending on each of the view-indicators of the data fields, the view selector module determines which data fields are shown by the interface module.

8. The method according to claim 1, wherein each of the input and output data fields further comprise one or more of a component indicator, a package indicator, a project indicator and a unit associated to the value.

9. The method according to claim 1, wherein the input and output data fields of a knowledge model are stored in the database as one or more of a flat file, a structured file, a relational table file or an XML data file.

10. The method according to claim 1, wherein each of the input and output data fields of a knowledge model are stored in the database as a string in a flat file, preferably wherein elements of a data field in a string of a flat file are separated by means of a separation symbol.

11. The method according Method according to claim 1, wherein a CAD-knowledge model can be exported from the database as one or more of a flat file, a structured file, a relational table file or an XML data file.

12. Computer system for providing insights on user desirability, the computer system comprising a database for managing a plurality of computer-aided design (CAD) knowledge models, wherein the database comprises for each knowledge model a plurality of input and output data fields and a plurality of calculation modules, wherein each data field comprises a data slot for receiving a value and a CAD-identifier corresponding to a parameter of a parametric CAD-model, wherein each calculation module couples a value of a corresponding input and output data slot via a formula, wherein the computer system is configured for:
obtaining a set of training records for each input CAD-identifier, wherein each of said training records is obtained by:
receiving a starting training input value in one of the input data slots of the database, wherein for said starting training input value a corresponding starting training output value is obtained by means of one or more corresponding calculation modules;
obtaining a modification to the starting training input or output value, wherein for said modified value a proposed corresponding training input or output value is obtained for said knowledge model by means of one or more corresponding calculation modules;
obtaining an acceptation indicator for the proposed corresponding training input or output value, wherein said input and output values are thereby registered as a desired training input or output value;
wherein each of said training records at least comprises the starting training input value and the corresponding desired training input value;
training a computer-implemented machine learning module for each input CAD-identifier based on the corresponding set of training records; providing a starting input value in an input data slot of a CAD-knowledge model, wherein for said starting input value a corresponding output value is obtained by means of one or more corresponding calculation modules;
obtaining a proposed desired input value for said starting input value by means of the trained computer-implemented machine learning module.

13. Computer program product for providing insights on user desirability, comprising instructions for:
providing a database for managing a plurality of computer-aided design (CAD) knowledge models, wherein the database comprises for each knowledge model a plurality of input and output data fields and a plurality of calculation modules, wherein each data field comprises a data slot for receiving a value and a CAD-identifier corresponding to a parameter of a parametric CAD-model, wherein each calculation module couples a value of a corresponding input and output data slot via a formula;
obtaining a set of training records for each input CAD-identifier, wherein each of said training records is obtained by:
receiving a starting training input value in one of the input data slots of the database, wherein for said starting training input value a corresponding starting training output value is obtained by means of one or more corresponding calculation modules;
obtaining a modification to the starting training input or output value, wherein for said modified value a proposed corresponding training input or output value is obtained for said knowledge model by means of one or more corresponding calculation modules;
obtaining an acceptation indicator for the proposed corresponding training input or output value, wherein said input and output values are thereby registered as a desired training input or output value;
wherein each of said training records at least comprises the starting training input value and the corresponding desired training input value;
training a computer-implemented machine learning module for each input CAD-identifier based on the corresponding set of training records; providing a starting input value in an input data slot of a CAD-knowledge model, wherein for said starting input value a corresponding output value is obtained by means of one or more corresponding calculation modules;
obtaining a proposed desired input value for said starting input value by means of the trained computer-implemented machine learning module.

14. Use of the computer-implemented method according to claim 1, for providing insights on user desirability of cooling installations.

15. Use of the computer-implemented method according to claim 12 for providing insights on user desirability of cooling installations.

16. Use of the computer-implemented method according to claim 13 for providing insights on user desirability of cooling installations.
